(19) United States
(12) Patent Application Publication
(10) Pub. No.: US 2012/0274493 A1
(43) Pub. Date: Nov. 1, 2012

(54) Digital-to-Analog Converter circuit with Rapid Built-in Self-test and Test Method

(76) Inventor: Shun-Hsun Yang, Hsinchu City (TW)

(21) Appl. No.: 13/457,452

(22) Filed: Apr. 26, 2012

(30) Foreign Application Priority Data
Apr. 29, 2011 (TW) 100115007

(51) Int. Cl. H03M 1/10

(52) U.S. Cl. 341/120

(57) ABSTRACT

A digital-to-analog converter circuit with rapid built-in self-test is disclosed. The digital-to-analog converter includes a control unit for generating a selection control signal and a digital data control signal, a voltage switching module including a voltage switching module for receiving a first test voltage, a second testing end for receiving a second test voltage, and a plurality of switches, which is utilized for respectively arranging each switch to connect to the first testing end or the second testing end to output the corresponding switching selection signal, and a digital-to-analog converter for selecting an output testing voltage signal from the plurality of switching selection signals according to the digital data control signal.

### BACKGROUND OF THE INVENTION

1. Field of the Invention

The present invention relates to a digital -to-analog converter circuit and related test method, and more particularly, to a digital-to-analog converter circuit with rapid built-in self-test functionalities, and related test method.

2. Description of the Prior Art

An digital-to-analog converter (DAC) is a crucial component in source driving circuits of Liquid Crystal Display (LCD) devices. In practical applications, due to non- symmetric components, defective components or intrinsic parasitic capacitance effect in the components, digital-to-analog converters often exhibit non-ideal characteristics, e.g. offset errors or non-linearity errors, causing output signal distortion during conversion processes, such that corresponding analog signals cannot be accurately converted. As a result, the source driving circuit would be incapable of driving corresponding pixels with precision to implement correct display.

Therefore, during fabrication of circuit chips, manufacturers perform tests on the source driving circuit 10 to ensure each outputted grayscale voltage level of the source driving circuit 10 is within regulated error ranges. Please refer to FIG. 1, which is a schematic diagram of a conventional source driving circuit 10. The source driving circuit 10 includes a shift register 102, data latches 104 and 106, a level shifter 108, a digital-to-analog converter 110, a grayscale level generator 112 and an output stage 114. Please refer to FIG. 2, which is a schematic diagram of timing waveforms of related signals in the source driving circuit 10. After the starting pulse signal STV and the clock signal CLK are inputted into the shift register 102, data starts to be received, and the data latch 104 sequentially stores the input data signals S1-Sn according to scan signals Q1-Qn sequentially generated by the shift register 102 (as shown by latch signals DL11-DL1n in FIG. 2). Next, on a rising edge of the data latch pulse signal SL, the input data signals S1-Sn originally stored in the data latch 104 are transmitted to the data latch 106 (as shown by the latch signals DL21-DL2n in FIG. 2). After that, the input data signals S1-Sn are converted to high-voltage input data signals S1-Sn by the level shifter 108. The digital-to-analog converter 110 then generates corresponding grayscale analog output signals according to the high-voltage input data signals S1-Sn and the grayscale voltage signals generated by the grayscale level generator 112. On a falling edge of the data latch pulse signal SL, the analog output signals Y1-Yn can be outputted by the output stage 114 directly for evaluating offset situation of grayscale voltage levels. Generally, before chips are ready for delivery, the source driving circuit 10 needs to be tested for every supported grayscale level so as to ensure the corresponding grayscale voltage levels are within regulated error range. However, since testing each grayscale level requires an input time (from the beginning of the starting pulse signal STV to the end of the data latch pulse signal SL) to sequentially input the data signals S1-Sn, as well as a setting time TS required by the testing platform (from after the analog output signals Y1-Yn are outputted, to until the outputted signals reach steady state), wherein the setting time TS for signals to reach steady states dominates the entire testing time. For example, if the source driving circuit 10 has an m-bit input, a total of 2^{m} grayscale values are provided, and the grayscale level generator 112 provides a total of 2^{m} grayscale voltage values. During circuit testing, a time duration of at least (2^{m}×TS) is required to finish testing offset errors for all grayscale levels.

On the other hand, LCD devices are becoming widely used in low-power mobile electronic products, thus DC power consumption at the output stage 112 is reduced. This further increases the setting time TS required for signals to reach steady state, as well as the overall testing time.

### SUMMARY OF THE INVENTION

Therefore, a primary objective of the present invention is to provide a digital-to-analog converter circuit with rapid built-in self-test and related test method.

In an embodiment, a digital-to-analog converter circuit with rapid built-in self-test is disclosed. The digital-to-analog converter circuit comprises a control unit, for generating a selection control signal and a digital data control signal according to a test start signal; a voltage switching module, coupled to the control unit, for generating a plurality of switching selection signals according to the selection control signal, the voltage switching module comprising a first testing end, for receiving a first test voltage; a second testing end, for receiving a second test voltage; and a plurality of switches, wherein each switch is coupled to the first testing end and the second testing end, and the voltage switching module switches the each switch to the first testing end or the second testing end, respectively, according to the selection control signal, to output the corresponding switching selection signal; and a digital-to-analog converter, coupled to the plurality of switches and the control unit, for receiving the plurality of switching selection signals, and selecting an output test voltage from the plurality of switching selection signals according to the digital data control signal.

In another embodiment, a test method for a digital-to-analog converter circuit is disclosed. The test method comprises generating a selection control signal and a digital data control signal according to a test start signal; generating a plurality of switching selection signals according to the selection control signal; and selecting an output test voltage from the plurality of switching selection signals according to the digital data control signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional source driving circuit.

FIG. 2 is a schematic diagram of timing waveforms of related signals in the source driving circuit shown in FIG. 1.

FIG. 3 is a schematic diagram of a source driving circuit according to an embodiment.

FIG. 4 is a schematic diagram of a digital-to-analog converter circuit shown in FIG. 3.

FIG. 5 is a schematic diagram of the digital-to-analog converter circuit shown in FIG. 3 during a normal operation mode.

FIGS. 6 and 7 are schematic diagrams of the digital-to-analog converter circuit shown in FIG. 3 during a test mode.

FIGS. 8 to 11 are schematic diagrams of variations of the digital-to-analog converter circuit shown in FIG. 3 during the test mode.

FIG. 12 is a schematic diagram of a test process according to an embodiment.

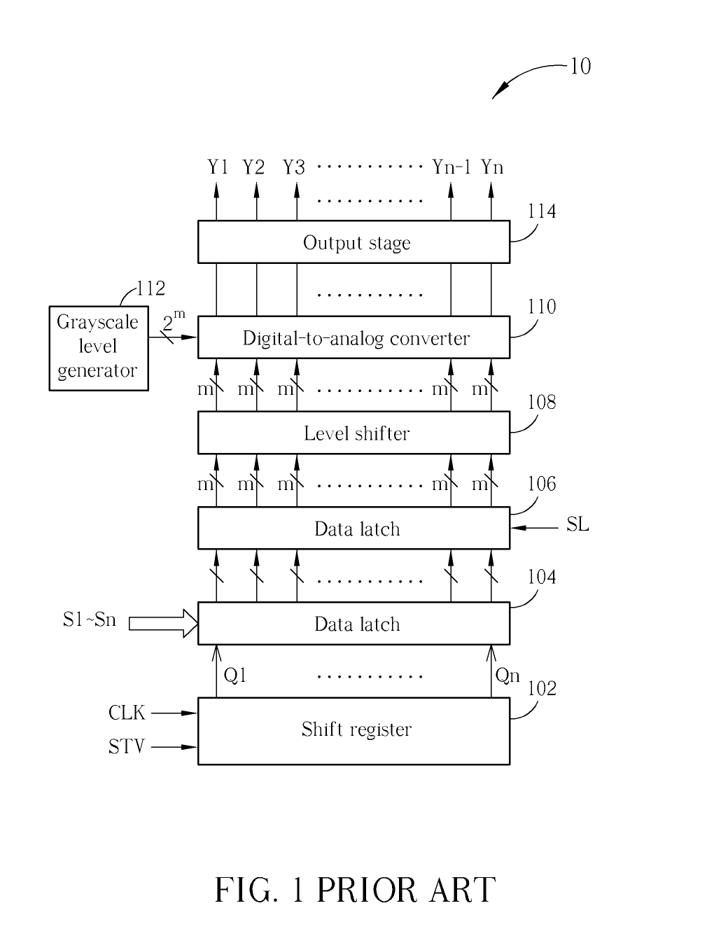

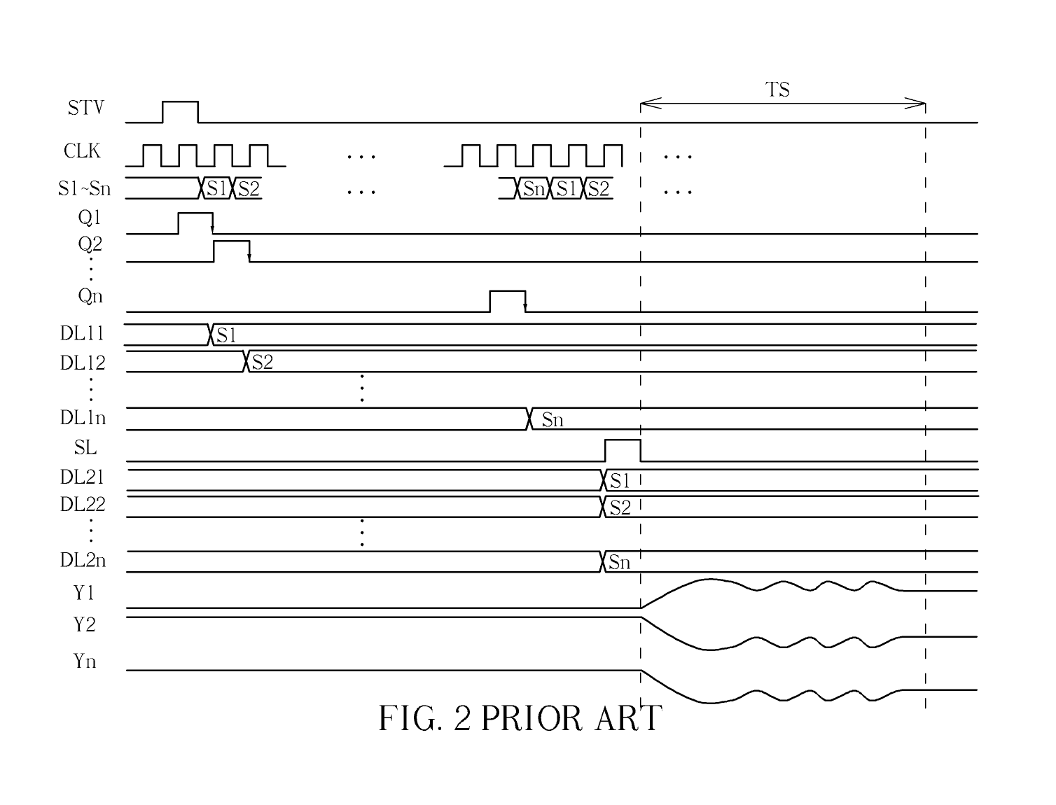

### DETAILED DESCRIPTION

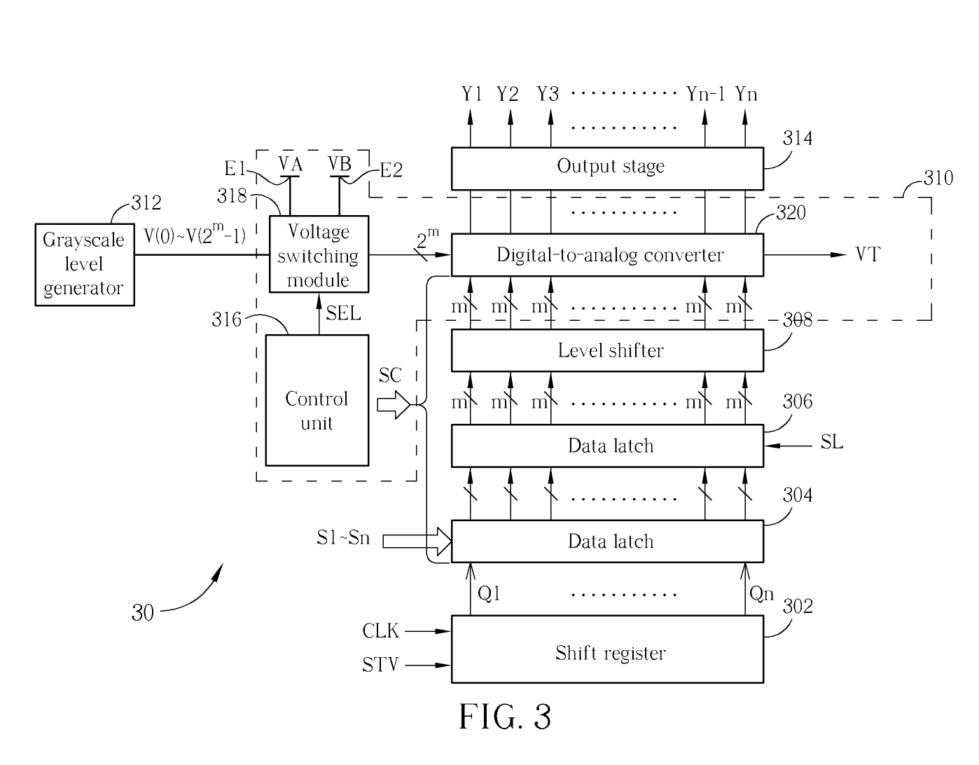

Please refer to FIG. 3, which is a schematic diagram of a source driving circuit 30 according to an embodiment. As shown in FIG. 3, the source driver 30 includes a shift register 302, data latches 304 and 306, a level shifter 308, a digital-to-analog converter circuit 310, a grayscale level generator 312 and an output stage 314. The digital-to-analog converter circuit 310 includes a control unit 316, a voltage switching module 318 and a digital-to-analog converter 320. During a normal operation mode of the source driving circuit 30, the shift register 302 sequentially generates scan signals Q1-Qn according to a starting pulse signal STV and a clock signal CLK. The data latch 304 sequentially stores input data signals S1-Sn according to the scan signals Q1-Qn. The data latch 306 stores the input data signals S1-Sn according to a data latch pulse signal SL, wherein each input data signal is an m-bit data signal. Next, the level shifter 308 converts the input data signals S1-Sn to high-voltage input data signals S1-Sn. The digital-to-analog converter circuit 310 generates corresponding grayscale analog output signals Y1-Yn according to the high-voltage input data signals S1-Sn and grayscale voltage signals V(0)-V(2^{m}-1) generated by the grayscale level generator 312. The output stage 314 is utilized for outputting the analog output signals Y1-Yn to an LCD panel, to implement pixel display of the LCD panel. During a test mode of source driving circuit 30, the digital-to-analog converter circuit 310 performs a test procedure for grayscale offset errors to ensure voltage levels corresponding to each grayscale level outputted by the source driving circuit 30 are within regulated error range, via collaborative operation of the control unit 316, the voltage switching module 318 and the digital-to-analog converter 320.

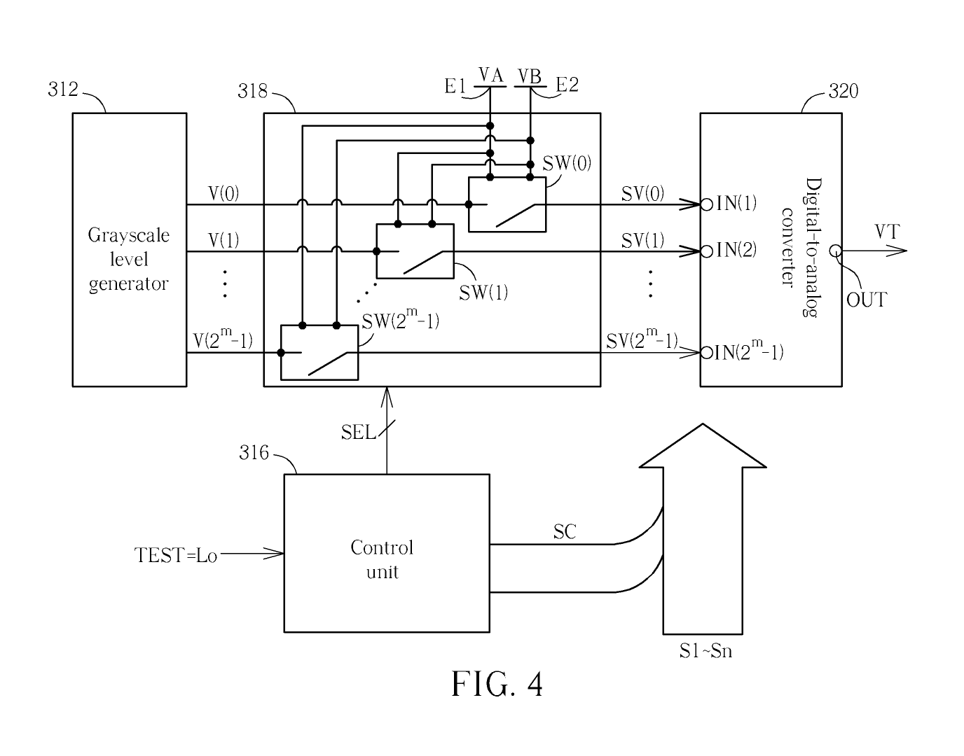

Please refer to FIG. 4, which is a schematic diagram of the digital-to-analog converter circuit 310 shown in FIG. 3. In the digital-to-analog converter circuit 310, the control unit 316 is utilized for generating a selection control signal SEL and a digital data control signal SC according to a test start signal TEST, wherein the digital data control signal SC is an m-bit data signal. As shown in FIG. 4, the voltage switching module 318 includes testing ends E1, E2 and switches SW(0)-SW(2^{m}-1), wherein the testing end E1 is utilized for receiving a test voltage VA, and the testing end E2 is utilized for receiving a test voltage VB, wherein the test voltages VA and VB maybe arbitrary voltage signals, respectively. Each switch is coupled to the testing end E1, the testing end E2 and the grayscale level generator 312. The voltage switching module 318 can connect each switch to the testing ends E1, E2 or the grayscale level generator 312, respectively, according to the selection control signal SEL, to output the corresponding switching selection signals. In other words, the voltage switching module 318 can select a connection for each switch, to generate the switching selection signals SV(0)-SV(2^{m}-1) according to the selection control signal SEL. For example, during the normal operation mode of the source driving circuit 30, the voltage switching module 318 controls the switches to connect to the grayscale level generator 312, to receive the grayscale voltages signal V(0)-V (2^{m}-1) , respectively. During the test mode of the source driving circuit 30, the voltage switching module 318 controls the switches to be connected to the testing end E1 or the testing end E2, to output the corresponding switching selection signals.

The digital-to-analog converter 320 includes input ends IN(0)-IN(2^{m}-1) and an output end OUT, wherein the input ends IN(0)-IN(2^{m}-1) are coupled to the switches SW(0)-SW(2^{m}-1), respectively, to receive the corresponding switching selection signals. During the normal operation mode, the digital-to-analog converter 320 connects one of the input ends IN(0)-IN(2^{m}-1) to the output end OUT according to the input data signals S1-Sn generated by the level shifter 308, so as to output the corresponding analog output signals to the output stage 314 via the output end OUT.

During the test mode, the digital-to-analog converter 320 connects one of the input ends IN(0)-IN(2m-1) to the output end OUT according to the digital data control signal SC, to output an output test voltage VT via the output end OUT. For example, during the test mode, each of the switches in the voltage switching module 318 can be sequentially connected to a same voltage terminal (e.g. the testing end E1) through arrangements of the control unit 316, and concurrently sequentially switches the corresponding input ends to the output end OUT via the digital-to-analog converter 320. In this way, it is possible to evaluate voltage offset errors for each grayscale via observing voltage level variations of the output test voltage VT at the output end OUT, and thereby achieving rapid self-test.

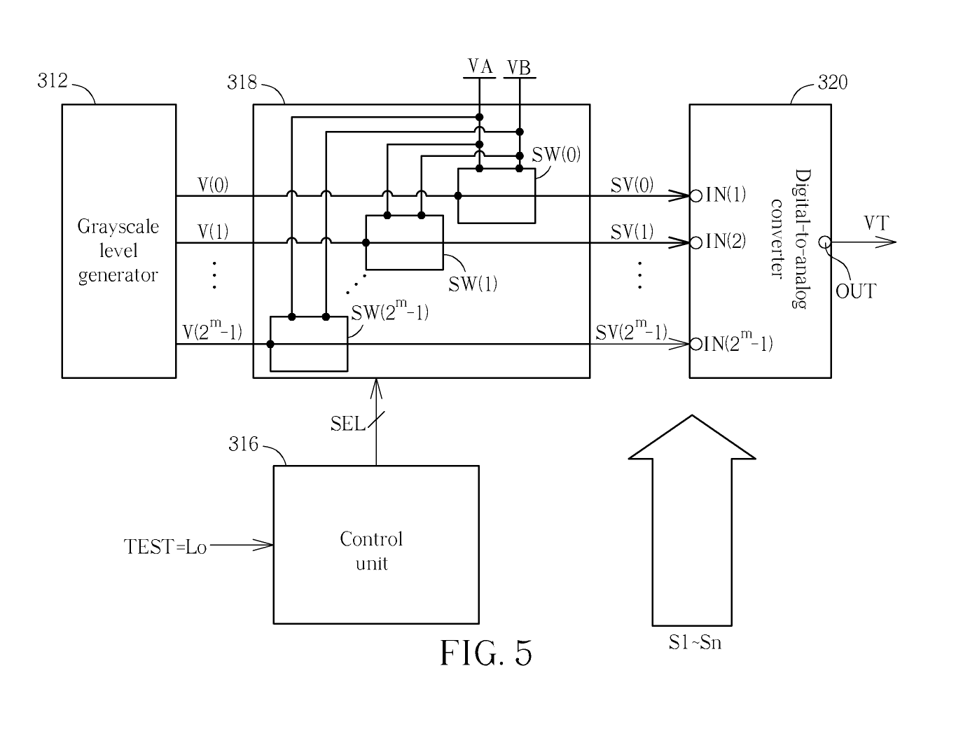

In more detail, during the normal operation mode of the source driving circuit 30 (assuming the test start signal TEST is at a low voltage level (i.e. TEST=Lo)) , please refer to FIG. 5, which is a schematic diagram of the digital-to-analog converter circuit 310 during the normal operation mode. The control unit 316 generates the corresponding selection control signal SEL to the voltage switching module 318. In such a case, the voltage switching module 318 controls each of the switches to be connected to the grayscale level generator 312, to receive the grayscale voltage signals V(0)-V (2^{m}-1), respectively. The digital-to-analog converter 320 connects one of the input end IN (1)-IN (2^{m}-1) to the output end OUT according to the input data signals S1-Sn generated by the level shifter 308, to output the corresponding analog output signal via the output end OUT. In other words, during the normal operation mode of the source driving circuit 30, the digital-to-analog converter 320 performs original digital-to-analog conversions.

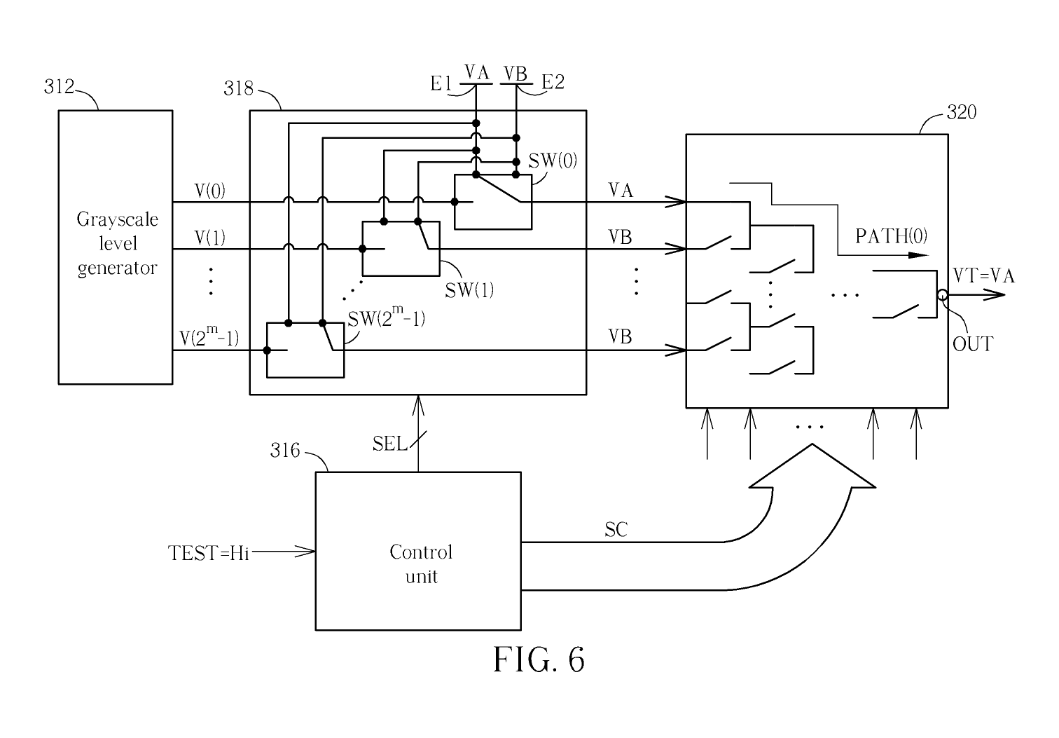

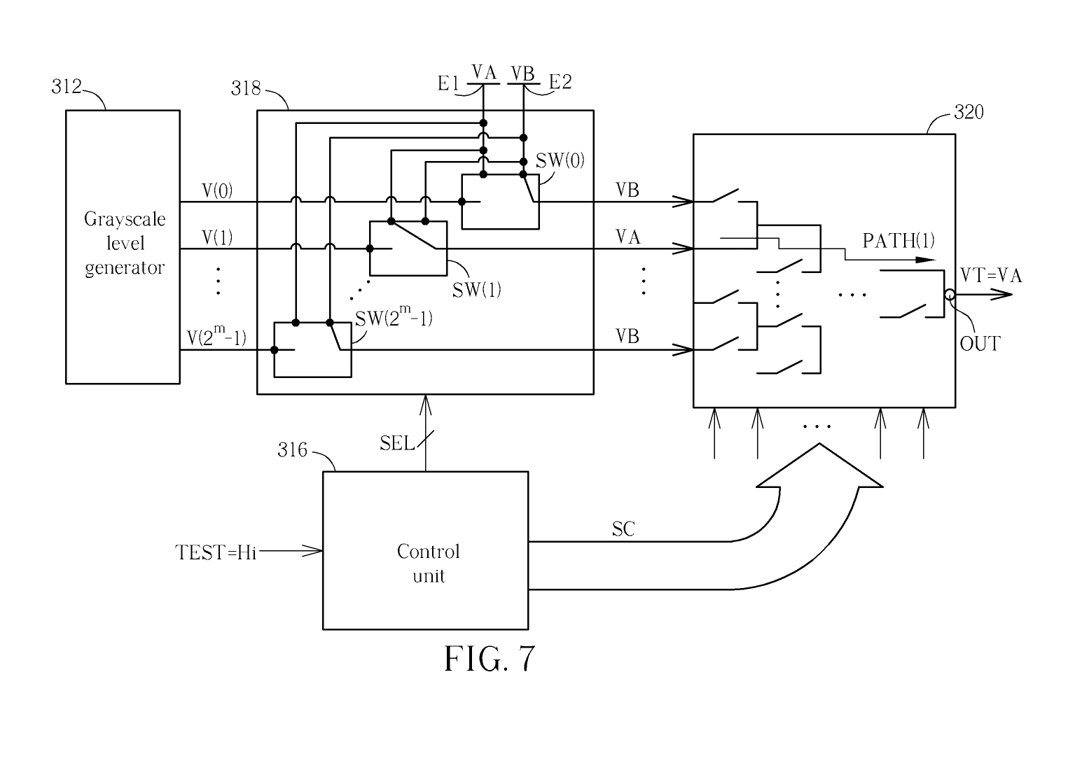

During the test mode of the source driving circuit 30 (assuming the test start signal TEST is at a high voltage level (i.e. TEST=Hi)), the control unit 316 generates the corresponding selection control signal SEL to the voltage switching module 318 according to the test start signal TEST, such that each of the switches is connected to the testing end E1 or the testing end E2. For example, as shown in FIG. 6, during a test period T1, the voltage switching module 318 connects the switch SW(0) to the testing end E1 according to the selection control signal SEL, and connects the switches SW(1)-SW(2^{m}-1) to the testing end E2. In such a case, the switch SW(0) outputs the test voltage VA to the input end IN(0), and the switches SW(1)-SW(2^{m}-1) output the test voltage VB to the input ends IN(1)-IN(2^{m}-1), respectively. The digital-to-analog converter 320 connects the input end IN(0) to the output end OUT according to the digital data control signal SC (the digital-to-analog converter 320 conducts a path PATH(0)), and outputs the corresponding output test voltage VT via the output end OUT. Therefore, through verifying voltage levels of the output test voltage VT, it is possible to determine whether voltage offset has occurred in the path PATH (0), originally for outputting the grayscale voltage signal V(0). For example, when the voltage level of the output test voltage VT equals the voltage level of the test voltage VA, or the two differ by a negligible difference, it represents that the signal path for outputting the corresponding grayscale voltage signal is operating normally with no voltage offset errors. Similarly, when the voltage level of the output test voltage VT does not equal the voltage level of the test voltage VA, or the two differ by a certain difference, it represents that voltage offset error has occurred in the signal path for outputting the corresponding grayscale voltage signal. Next, as shown in FIG. 7, during a test period T2, the voltage switching module 318 connects the switch SW(1) to the testing end El according to the selection control signal SEL, and connects the switches SW(0) and SW(2)-SW(2^{m}-1) to the testing end E2. In such a case, the switch SW(1) outputs the test voltage VA to the input end IN(1). The digital-to-analog converter 320, connects the input end IN(1) to the output end OUT (the digital-to-analog converter 320 conducts the path PATH(1)) according to the digital data control signal SC, and outputs the corresponding output test voltage VT via the output end OUT. In the same way, via determining whether the voltage level of the output test voltage VT equals the voltage level of the test voltage VA, it is possible to determine whether voltage offset has occurred in the path PATH(1), originally for outputting the grayscale voltage signal V(1). Similarly, the switches SW(3)-SW(2^{m}-1) are sequentially connected to the testing end E1. As such, during each test period, the path conducted by the digital-to-analog converter 320 transmits the test voltage VA, it is therefore possible to rapidly test offset errors in grayscale voltage levels of the digital-to-analog converter 320 via observing voltage level variations of the test voltage VT.

Moreover, the aforementioned operations for determining the voltage level of the output test voltage VT may be implemented via a determining unit (not shown). For example, the determining unit may be integrated into the source driver 30 or integrated into a testing platform. As such, during circuit chip fabrication, it is possible to test offset errors in the grayscale voltage level accordingly via the determining unit detecting and determining the voltage level of the output test voltage VT and variations thereof.

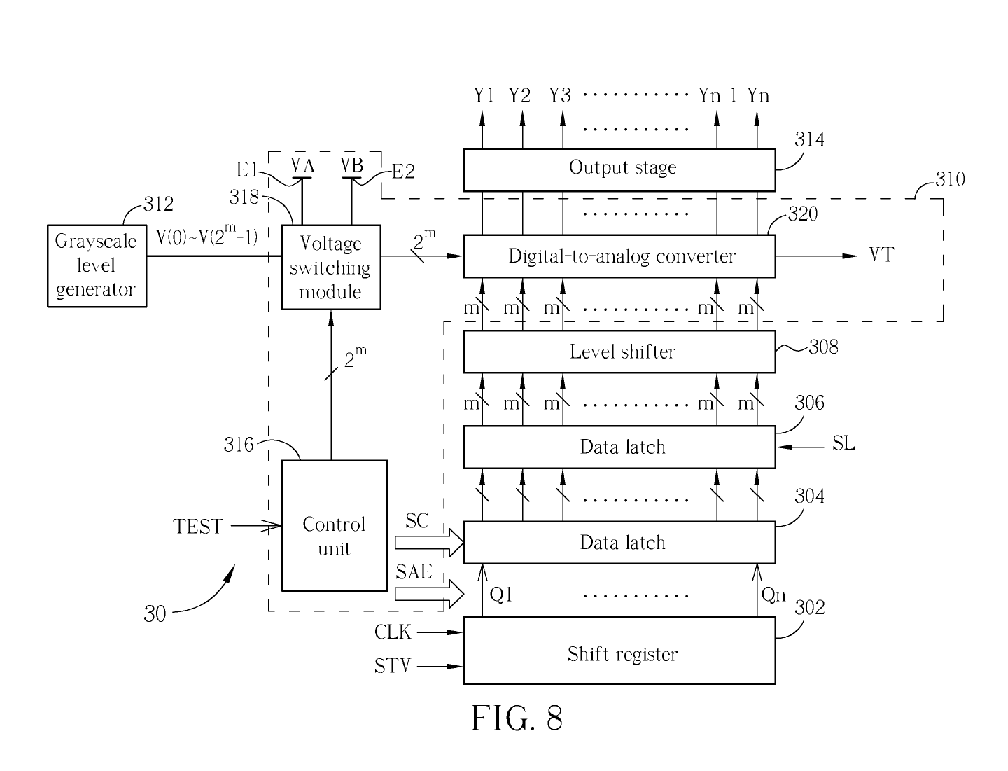

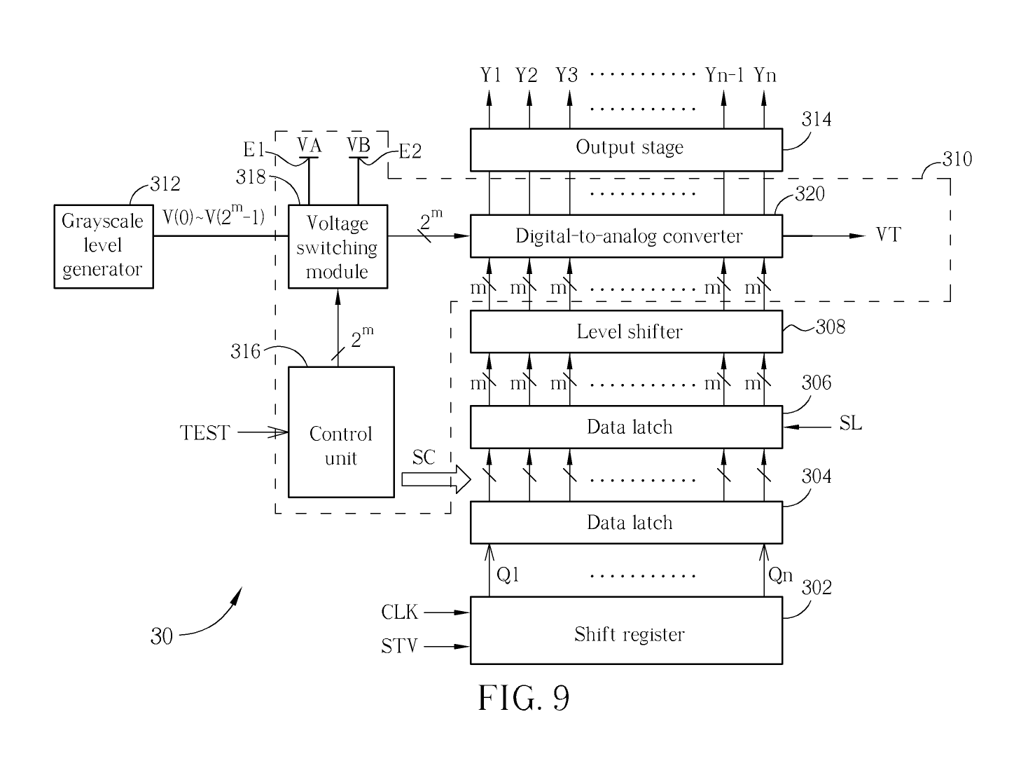

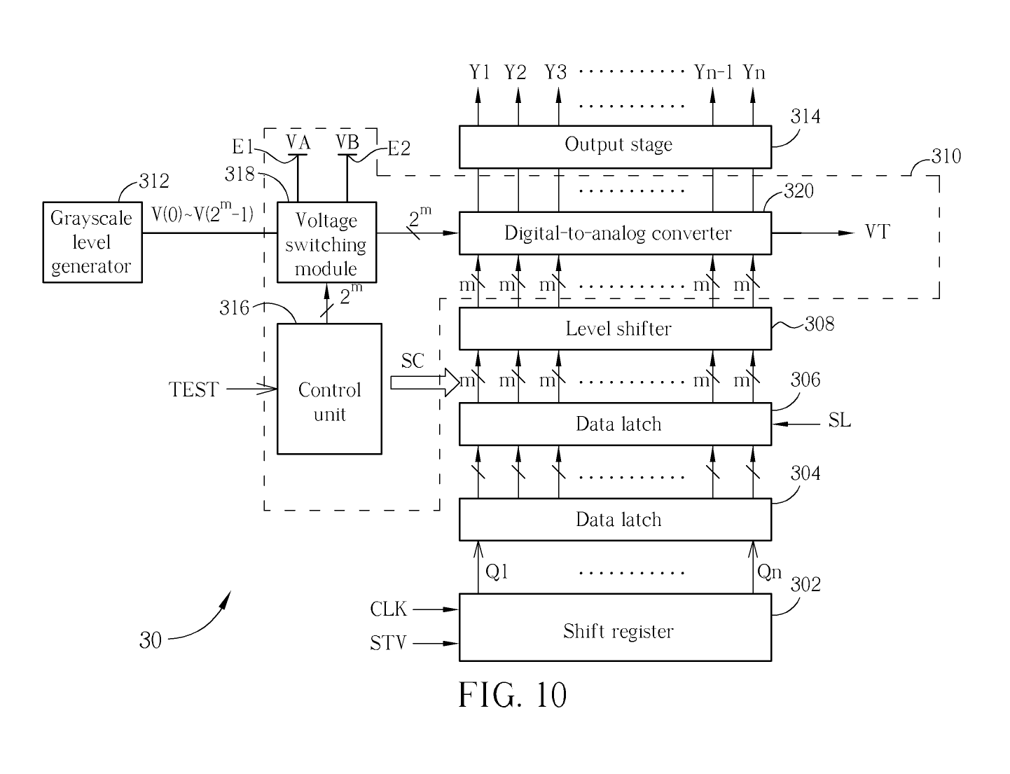

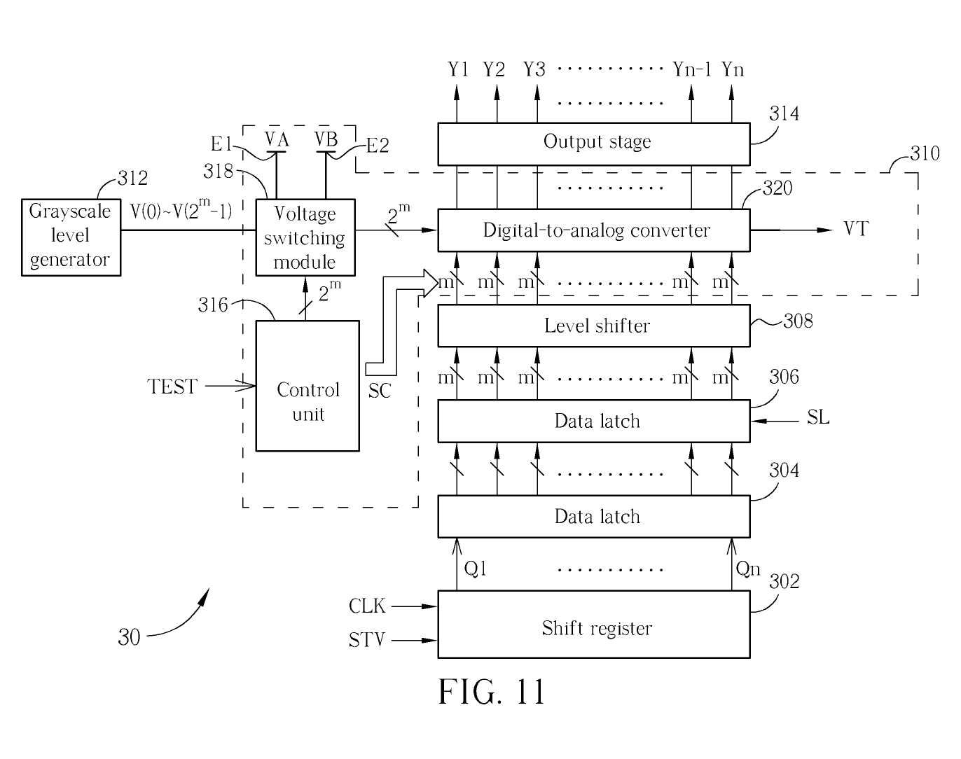

Please refer to FIGS. 8 to FIG. 11, which are schematic diagrams of variations of the digital-to-analog converter circuit 310 during the test mode, respectively. In FIG. 8, an enable-all signal SAE is utilized to allow data latch 304 simultaneously access the digital data control signal SC, to sequentially turn on all of the conduction paths of the digital-to-analog converter 320, such that the output test voltage VT equals the test voltage VA. In FIG. 9, the digital data control signal SC is positioned on the output path of the data latch 304, so as to sequentially turn on digital-to-analog converter 320, such that the output test voltage VT equals the test voltage VA. In FIGS. 10 and 11, the digital data control signal SC placed on the output paths of the data latch 306 and the level shifter 308, respectively, to sequentially turn on each conduction path of the digital-to-analog converter 320, such that the output test voltage VT equals the test voltage VA.

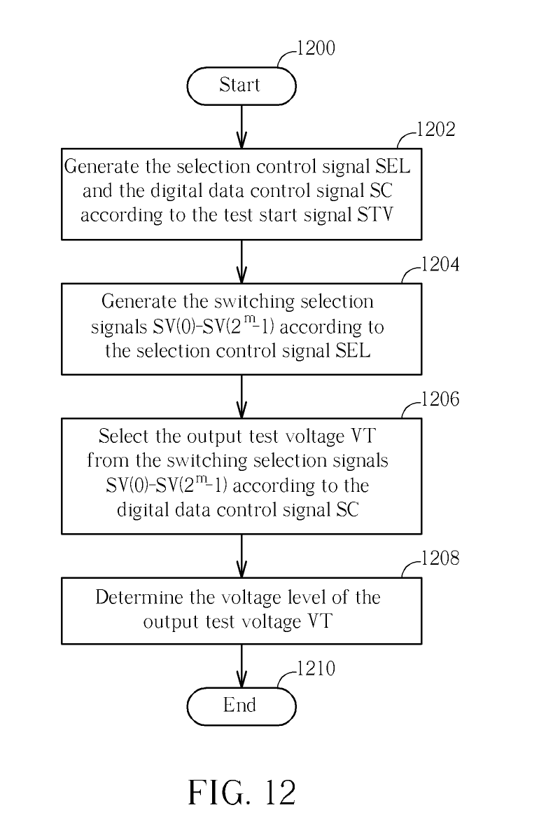

Operations of the digital-to-analog converter circuit 310 may be summarized into a test process 120, as shown in FIG. 12. The test process 120 includes the following steps:

Step 1200: Start.

Step 1202: Generate the selection control signal SEL and the digital data control signal SC according to the test start signal STV.

Step 1204: Generate the switching selection signals SV(0)-SV(2^{m}-1) according to the selection control signal SEL.

Step 1206: Select the output test voltage VT from the switching selection signals SV(0)-SV(2^{m}-1) according to the digital data control signal SC.

Step 1208: Determine the voltage level of the output test voltage VT.

Step 1210: End.

Details of the test process 120 may be found in the aforementioned descriptions, and are not reiterated herein.

In summary, the present invention tests offset errors in each outputted grayscale voltage level via an analog-to-digital convertor with self-test functionalities. Compared with the prior art, the present invention does not require a prolonged output stabilization waiting time, and is therefore capable of effectively shortening the test time, and thereby achieving rapid self-test.

Those skilled in the art will readily observe that numerous modifications and alterations of the device and method may be made while retaining the teachings of the invention.

What is claimed is:

1. A digital-to-analog converter circuit with rapid built-in self-test, comprising:
a control unit, for generating a selection control signal and a digital data control signal according to a test start signal;
a voltage switching module, coupled to the control unit, for generating a plurality of switching selection signals according to the selection control signal, the voltage switching module comprising:
a first testing end, for receiving a first test voltage;
a second testing end, for receiving a second test voltage; and
a plurality of switches, wherein each switch is coupled to the first testing end and the second testing end, and the voltage switching module switches the each switch to the first testing end or the second testing end, respectively, according to the selection control signal, to output the corresponding switching selection signal; and
a digital-to-analog converter, coupled to the plurality of switches and the control unit, for receiving the plurality of switching selection signals, and selecting an output test voltage from the plurality of switching selection signals according to the digital data control signal.

2. The digital-to-analog converter circuit of claim 1, wherein the voltage switching module connects a first switch of the plurality of switches to the first testing end according to the selection control signal.

3. The digital-to-analog converter circuit of claim 2, wherein the digital-to-analog converter comprises:
a plurality of input ends, coupled to the plurality of switches, respectively, for receiving the plurality of switching selection signals; and
an output end, wherein the digital-to-analog converter connects an input end of the plurality of input ends corresponding to the first switch to the output end according to the digital data control signal, to output the output test voltage at the output end.

4. The digital-to-analog converter circuit of claim 2, wherein the voltage switching module sequentially connects the plurality of switches to the first testing end according to the selection control signal.

5. The digital-to-analog converter circuit of claim 4, wherein the voltage switching module sequentially connects the plurality of switches to the first testing end according to the selection control signal at intervals of a test period.

6. The digital-to-analog converter circuit of claim 1 further comprising a determining unit, coupled to the digital-to-analog converter, for determining a voltage level of the output test voltage.

7. The digital-to-analog converter circuit of claim 1 further comprising a grayscale level generator, coupled to the plurality of switches of the voltage switching module, for generating a plurality of grayscale voltage signals to be transmitted to the corresponding switches, respectively.

8. A test method for a digital-to-analog converter circuit, comprising:
generating a selection control signal and a digital data control signal according to a test start signal;
generating a plurality of switching selection signals according to the selection control signal; and
selecting an output test voltage from the plurality of switching selection signals according to the digital data control signal.

9. The test method of claim 8, wherein the step of generating the plurality of switching selection signals according to the selection control signal comprises:
outputting a first switching selection signal corresponding to a first test voltage according to the selection control signal.

10. The test method of claim 9, wherein the step of selecting the output test voltage from the plurality of switching selection signals according to the digital data control signal comprises:
selecting the first switching selection signal from the plurality of switching selection signals as the output test voltage, according to the digital data control signal.

11. The test method of claim 8 further comprising:
determining a voltage level of the output test voltage.
